(19) United States
(12) Patent Application Publication
(10) Pub. No.: US 2024/0196546 A1
(43) Pub. Date: Jun. 13, 2024

(54) PRINTED WIRING BOARD

(71) Applicant: IBIDEN CO., LTD., Ogaki (JP)

(72) Inventors: Jun SAKAI, Ogaki (JP); Takuya INISHI, Ogaki (JP)

(73) Assignee: IBIDEN CO., LTD., Ogaki (JP)

(21) Appl. No.: 18/537,853

(22) Filed: Dec. 13, 2023

(30) Foreign Application Priority Data
Dec. 13, 2022 (JP) 2022-198926

(51) Int. Cl. H05K 3/42; H05K 3/46

(52) U.S. Cl. CPC H05K 3/423; H05K 3/4605; H05K 3/4644; H05K 2203/068; H05K 2203/0723

(57) ABSTRACT

A printed wiring board includes a laminate including resin insulating layers and conductor layers, and via conductors formed in via holes of the resin insulating layers and each including a seed layer and an electrolytic plating layer formed on the seed layer such that the via conductors connect the conductor layers adjacent to each other and that the via conductors include a first via conductor and a second via conductor formed on the first via conductor in a lamination direction of the laminate. The resin insulating layers include resin and inorganic particles such that the inorganic particles include first inorganic particles having smooth surfaces and second inorganic particles embedded in the resin insulating layers and that an inner wall surface of each of the via holes in the resin insulating layers includes the resin and the smooth surfaces of the first inorganic particles.

### CROSS-REFERENCE TO RELATED APPLICATIONS

The present application is based upon and claims the benefit of priority to Japanese Patent Application No. 2022-198926, filed Dec. 13, 2022, the entire contents of which are incorporated herein by reference.

### BACKGROUND OF THE INVENTION

### Field of the Invention

The present invention relates to a printed wiring board.

### Description of Background Art

Japanese Patent Application Laid-Open Publication No. 2005-268517 describes a multilayer wiring substrate in which multiple resin insulating layers and multiple wiring conductor layers are alternately laminated. The entire contents of this publication are incorporated herein by reference.

### SUMMARY OF THE INVENTION

According to one aspect of the present invention, a printed wiring board includes a laminate including resin insulating layers and conductor layers, and via conductors formed in via holes of the resin insulating layers and each including a seed layer and an electrolytic plating layer formed on the seed layer such that the via conductors connect the conductor layers adjacent to each other and that the via conductors include a first via conductor and a second via conductor formed on the first via conductor in a lamination direction of the laminate. The resin insulating layers include resin and inorganic particles such that the inorganic particles include first inorganic particles having smooth surfaces and second inorganic particles embedded in the resin insulating layers and that an inner wall surface of each of the via holes in the resin insulating layers includes the resin and the smooth surfaces of the first inorganic particles.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view schematically illustrating a printed wiring board according to an embodiment of the present invention;

FIG. 2 is an enlarged cross-sectional view schematically illustrating a portion of a printed wiring board according to an embodiment of the present invention;

FIG. 3A is a cross-sectional view schematically illustrating a method for manufacturing a printed wiring board according to an embodiment of the present invention;

FIG. 3B is a cross-sectional view schematically illustrating a method for manufacturing a printed wiring board according to an embodiment of the present invention;

FIG. 3C is a cross-sectional view schematically illustrating a method for manufacturing a printed wiring board according to an embodiment of the present invention;

FIG. 3D is an enlarged cross-sectional view schematically illustrating a method for manufacturing a printed wiring board according to an embodiment of the present invention;

FIG. 3E is a cross-sectional view schematically illustrating a method for manufacturing a printed wiring board according to an embodiment of the present invention;

FIG. 3F is a cross-sectional view schematically illustrating a method for manufacturing a printed wiring board according to an embodiment of the present invention;

FIG. 3G is a cross-sectional view schematically illustrating a method for manufacturing a printed wiring board according to an embodiment of the present invention;

FIG. 3H is a cross-sectional view schematically illustrating a method for manufacturing a printed wiring board according to an embodiment of the present invention; and

FIG. 4 is an enlarged cross-sectional view schematically illustrating a method for manufacturing a printed wiring board of a second alternative example according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

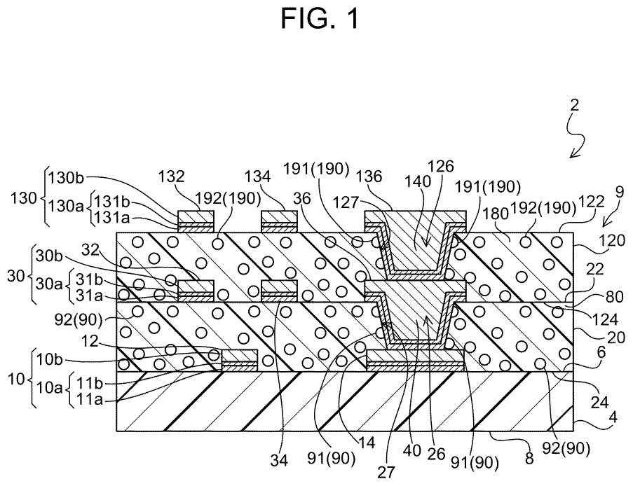

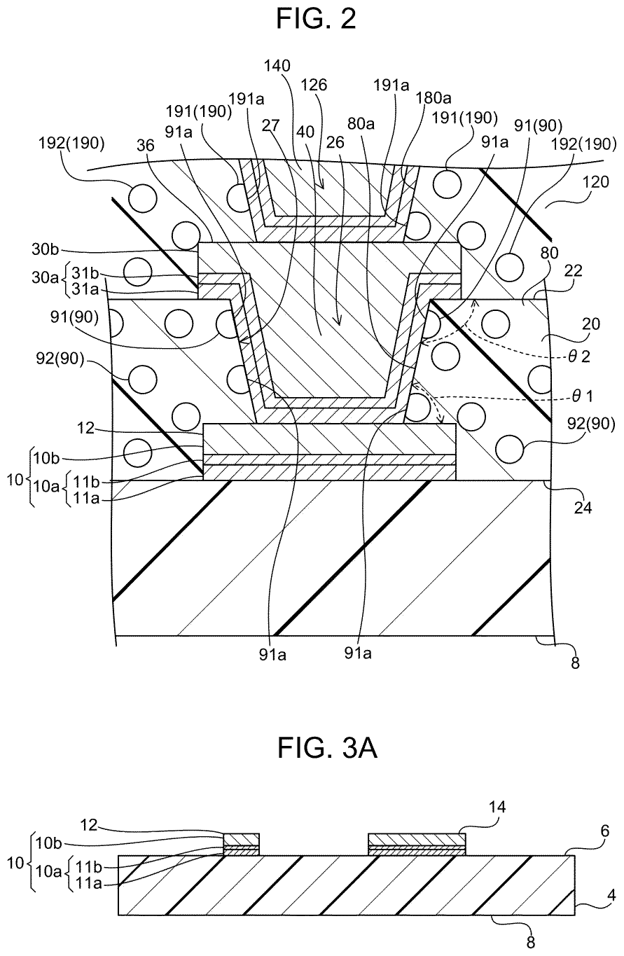

FIG. 1 is a cross-sectional view illustrating a printed wiring board 2 according to an embodiment of the present invention. FIG. 2 is an enlarged cross-sectional view illustrating a part of the printed wiring board 2 of the embodiment. As illustrated in FIG. 1, the printed wiring board 2 includes an insulating layer 4 and a laminate 9. The laminate 9 is formed by alternately laminating multiple resin insulating layers and multiple conductor layers. Specifically, the laminate 9 includes a first conductor layer 10, a first resin insulating layer 20, a second conductor layer 30, a first via conductor 40, a second resin insulating layer 120, a third conductor layer 130, and a second via conductor 140.

The insulating layer 4 is formed using a resin. The insulating layer 4 may contain inorganic particles such as silica particles. The insulating layer 4 may contain a reinforcing material such as a glass cloth. The insulating layer 4 has a third surface 6 (upper surface in the drawing) and a fourth surface 8 (lower surface in the drawing) on the opposite side with respect to the third surface 6.

The first conductor layer 10 is formed on the third surface 6 of the insulating layer 4. The first conductor layer 10 includes a signal wiring 12 and a pad 14. The first conductor layer 10 may also include a conductor circuit other than the signal wiring 12 and the pad 14. The first conductor layer 10 is mainly formed of copper. The first conductor layer 10 is formed of a seed layer (10a) on the insulating layer 4 and an electrolytic plating layer (10b) on the seed layer (10a). The seed layer (10a) is formed of a first layer (11a) on the third surface 6 and a second layer (11b) on the first layer (11a). The first layer (11a) is formed of an alloy (copper alloy) containing copper, silicon and aluminum. The second layer (11b) is formed of copper. The electrolytic plating layer (10b) is formed of copper. The first layer (11a) is in contact with the insulating layer 4.

The first resin insulating layer 20 is formed on the third surface 6 of the insulating layer 4 and on the first conductor layer 10. The first resin insulating layer 20 has a first surface 22 (upper surface in the drawing) and a second surface 24 (lower surface in the drawing) on the opposite side with respect to the first surface 22. The second surface 24 of the first resin insulating layer 20 faces the first conductor layer 10. The first resin insulating layer 20 contains a resin 80 and a large number of inorganic particles 90. The first resin insulating layer 20 has a via hole 26 as a through hole that penetrates the first resin insulating layer 20 in a thickness direction. An inner wall surface 27 of the via hole 26 is formed of the resin 80 and the inorganic particles 90. The inner wall surface 27 is formed smooth.

For the resin 80, for example, a thermosetting resin or a photocurable resin may be used. For the resin 80, as an example, an epoxy resin is used.

The large number of inorganic particles 90 are dispersed in the resin 80. For the inorganic particles 90, for example, silica or alumina particles may be used. The inorganic particles 90 have, for example, an average particle size of 0.5 μm and particle sizes in a range of 0.1 μm or more and 5.0 μm or less.

As illustrated in FIGS. 1 and 2, the inorganic particles 90 include first inorganic particles 91 and second inorganic particles 92. The first inorganic particles 91 have first smooth surfaces (91a) that form the inner wall surface 27 of the via hole 26. The second inorganic particles 92 are embedded in the resin 80. The second inorganic particles 92 each have, for example, a spherical shape. The first inorganic particles 91 each have, for example, a shape obtained by cutting a sphere with a plane. For example, the shapes of the first inorganic particles 91 are obtained by cutting the second inorganic particles 92 with a plane. The first inorganic particles 91 and the second inorganic particles 92 are different in shape. The first smooth surfaces (91a) are cut surfaces of the first inorganic particles 91.

As illustrated in FIG. 1, the first surface 22 of the first resin insulating layer 20 is formed only of the resin 80. No inorganic particles 90 are exposed from the first surface 22. Specifically, the second inorganic particles 92 are not exposed from the first surface 22. The first surface 22 does not include surfaces of the second inorganic particles 92. No unevenness is formed on the first surface 22 of the first resin insulating layer 20. The first surface 22 is not roughened. The first surface 22 is formed smooth. The first surface 22 has, for example, an arithmetic mean roughness (Ra) of 0.02 μm or more and 0.06 μm or less.

As illustrated in FIG. 2, the inner wall surface 27 of the via hole 26 is formed of a surface (80a) of the resin 80 and the first smooth surfaces (91a) of the first inorganic particles 91. The surface (80a) and the first smooth surfaces (91a) form a substantially common surface. In other words, the surface (80a) and the first smooth surfaces (91a) are flush with each other. Therefore, no unevenness is formed on the inner wall surface 27. That is, the inner wall surface 27 is smooth. The inner wall surface 27 has, for example, an arithmetic mean roughness (Ra) of 1.0 μm or less. In other words, the surface (80a) and the first smooth surfaces (91a) that form the inner wall surface 27 each have, for example, an arithmetic mean roughness (Ra) of 1.0 μm or less.

As illustrated in FIG. 2, the inner wall surface 27 of the via hole 26 is inclined. An angle (inclination angle) (01) between an upper surface of the pad 14 and the inner wall surface 27 is, for example, 70 degrees or more and 85 degrees or less. The upper surface of pad 14 is included in an upper surface of first conductor layer 10. An angle (inclination angle) (02) between the first surface (upper surface) 22 of the first resin insulating layer 20 and the inner wall surface 27 is, for example, 95 degrees or more and 110 degrees or less.

As illustrated in FIG. 1, the second conductor layer 30 is formed on the first surface 22 of the first resin insulating layer 20. The second conductor layer 30 includes a first signal wiring 32, a second signal wiring 34, and a land 36. The second conductor layer 30 may include a conductor circuit other than the first signal wiring 32, the second signal wiring 34, and the land 36. The first signal wiring 32 and the second signal wiring 34 form a pair wiring. The second conductor layer 30 is mainly formed of copper. The second conductor layer 30 is formed by a seed layer (30a) on the first surface 22 and an electrolytic plating layer (30b) on the seed layer (30a). The seed layer (30a) is formed of a first layer (31a) on the first surface 22 and a second layer (31b) on the first layer (31a). The first layer (31a) is formed of an alloy (copper alloy) containing copper, silicon and aluminum. The second layer (31b) is formed of copper. The electrolytic plating layer (30b) is formed of copper. The first layer (31a) is in contact with the first surface 22. The second layer (31b) adheres to the electrolytic plating layer (30b). A surface of the second conductor layer 30 facing the first surface 22 of the first resin insulating layer 20 is formed along a surface shape of the first surface 22. The second conductor layer 30 does not enter an inner side of the first surface 22 of the first resin insulating layer 20.

The first via conductor 40 is formed in the via hole 26. The first via conductor 40 connects the first conductor layer 10 and the second conductor layer 30 that are adjacent to each other in a lamination direction. The lamination direction is a direction in which the layers are laminated, and is the same direction as the thickness direction of the layers. In the present embodiment, the lamination direction is the same as an up-down direction. In FIG. 1, the first via conductor 40 connects the pad 14 and the land 36. The first via conductor 40 is formed of a seed layer (30a) and an electrolytic plating layer (30b) on the seed layer (30a). The seed layer (30a) forming the first via conductor 40 and the seed layer (30a) forming the second conductor layer 30 are common. The first layer (31a) is in contact with the inner wall surface 27.

The second resin insulating layer 120 is formed on the first surface 22 of the first resin insulating layer 20 and on the second conductor layer 30. The second resin insulating layer 120 has a fifth surface 122 (upper surface in the drawing) and a sixth surface 124 (lower surface in the drawing) on the opposite side with respect to the fifth surface 122. The sixth side 124 of the second resin insulating layer 120 faces the second conductor layer 30. The second resin insulating layer 120 contains a resin 180 and a large number of inorganic particles 190. The second resin insulating layer 120 has a via hole 126 as a through hole that penetrates the second resin insulating layer 120 in the thickness direction. An inner wall surface 127 of the via hole 126 is formed of the resin 180 and the inorganic particles 190. The inner wall surface 127 is formed smooth. The resin 180 and the inorganic particles 190 are respectively the same as the resin 80 and the inorganic particles 90 of the first resin insulating layer 20. The inorganic particles 190 include first inorganic particles 191 and second inorganic particles 192. The first inorganic particles 191 have first smooth surfaces (191a) that form the inner wall surface 127 of the via hole 126. The second inorganic particles 192 are embedded in the resin 180. The second inorganic particles 192 each have, for example, a spherical shape. The first inorganic particles 191 each have, for example, a shape obtained by cutting a sphere with a plane. For example, the shapes of the first inorganic particles 191 are obtained by cutting the second inorganic particles 192 with a plane. The first inorganic particles 191 and the second inorganic particles 192 are different in shape. The first smooth surfaces (191a) are cut surfaces of the first inorganic particles 191.

As illustrated in FIG. 1, the fifth surface 122 of the second resin insulating layer 120 is formed only of the resin 180. No inorganic particles 190 are exposed from the fifth surface 122. Specifically, the second inorganic particles 192 are not exposed from the fifth surface 122. The fifth surface 122 does not include surfaces of the second inorganic particles 192. No unevenness is formed on the fifth surface 122 of the second resin insulating layer 120. The fifth surface 122 is not roughened. The fifth surface 122 is formed smooth. An arithmetic mean roughness (Ra) of the fifth surface 122 may be substantially the same as the arithmetic mean roughness of the first surface 22.

As illustrated in FIG. 2, the inner wall surface 127 of the via hole 126 is formed of a surface (180a) of the resin 180 and the first smooth surfaces (191a) of the first inorganic particles 91. The surface (180a) and the first smooth surfaces (191a) form a substantially common surface. In other words, the surface (180a) and the first smooth surfaces (191a) are flush with each other. Therefore, no unevenness is formed on the inner wall surface 127. That is, the inner wall surface 127 is smooth. An arithmetic mean roughness of the inner wall surface 127 may be substantially the same as the arithmetic mean roughness of the inner wall surface 27. In other words, arithmetic mean roughness of the surface (180a) and the first smooth surfaces (191a) that form the inner wall surface 127 may be respectively the same as the arithmetic mean roughness of the surface (80a) and the first smooth surfaces (91a) that form the inner wall surface 27. Further, an inclination angle of the via hole 126 may be substantially the same as the inclination angle of the via hole 26.

As illustrated in FIG. 1, the third conductor layer 130 is formed on the fifth surface 122 of the second resin insulating layer 120. The third conductor layer 130 includes a first signal wiring 132, a second signal wiring 134, and a land 136. The third conductor layer 130 may include a conductor circuit other than the first signal wiring 132, the second signal wiring 134, and the land 136. The first signal wiring 132 and the second signal wiring 134 form a pair wiring. The third conductor layer 130 is mainly formed of copper. The third conductor layer 130 is formed by a seed layer (130a) on the fifth surface 122 and an electrolytic plating layer (130b) on the seed layer (130a). The seed layer (130a) and the electrolytic plating layer (130b) are similar to the seed layer (30a) and the electrolytic plating layer (30b) of the second conductor layer 30. The seed layer (130a) is formed by a first layer (131a) on the fifth surface 122 and a second layer (131b) on the first layer (131a). The first layer (131a) is formed of an alloy (copper alloy) containing copper, silicon and aluminum. The second layer (131b) is formed of copper. The electrolytic plating layer (130b) is formed of copper. The first layer (131a) is in contact with the fifth surface 122. A surface of the third conductor layer 130 facing the fifth surface 122 of the second resin insulating layer 120 is formed along a surface shape of the fifth surface 122. The third conductor layer 130 does not enter an inner side of the fifth surface 122 of the second resin insulating layer 120.

The second via conductor 140 is formed in the via hole 126. The second via conductor 140 connects the second conductor layer 30 and the third conductor layer 130 that are adjacent to each other in the lamination direction. In FIG. 1, the second via conductor 140 connects the land 36 and the land 136. The second via conductor 140 is formed of a seed layer (130a) and an electrolytic plating layer (130b) on the seed layer (130a). The seed layer (130a) forming the second via conductor 140 and the seed layer (130a) forming the third conductor layer 130 are common. The first layer (131a) is in contact with the inner wall surface 127. The first via conductor 40 and the second via conductor 140 overlap each other in the lamination direction.

### Method for Manufacturing Printed Wiring Board

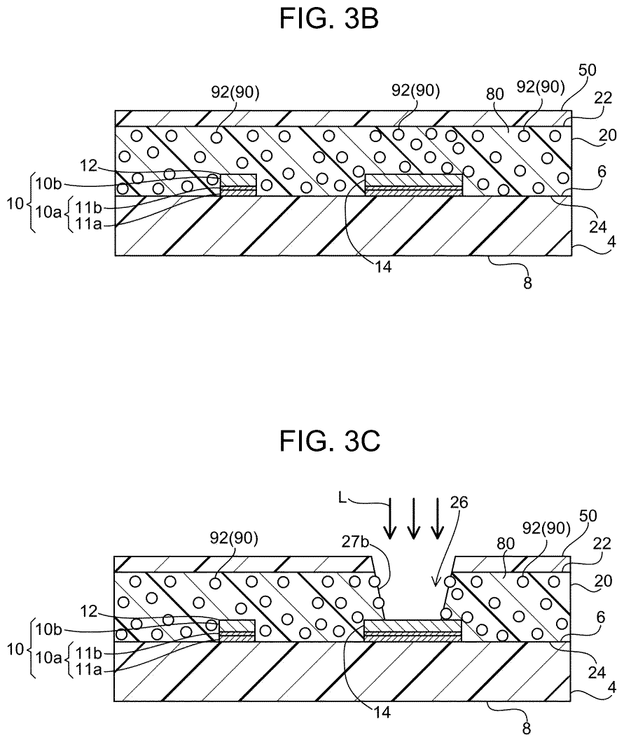

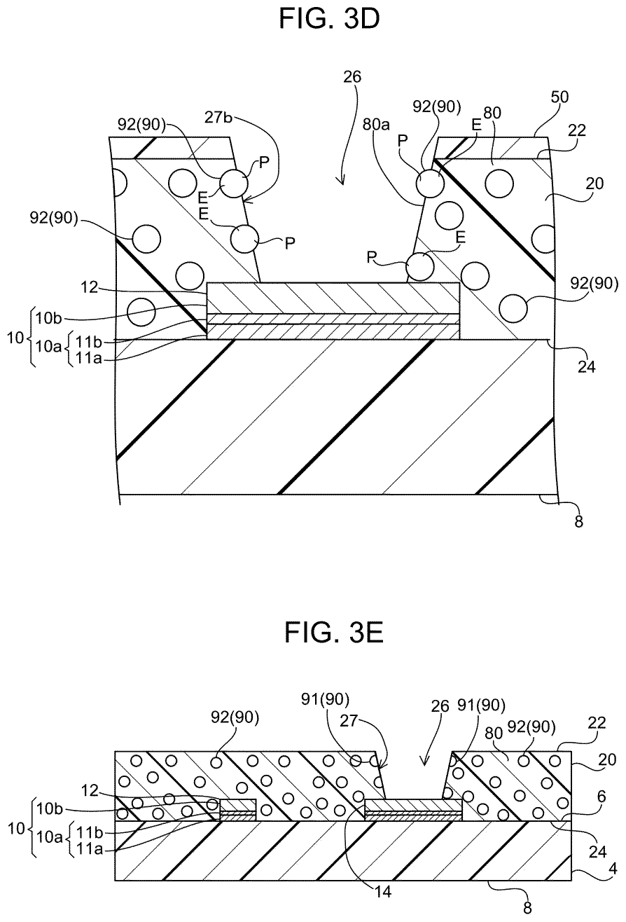

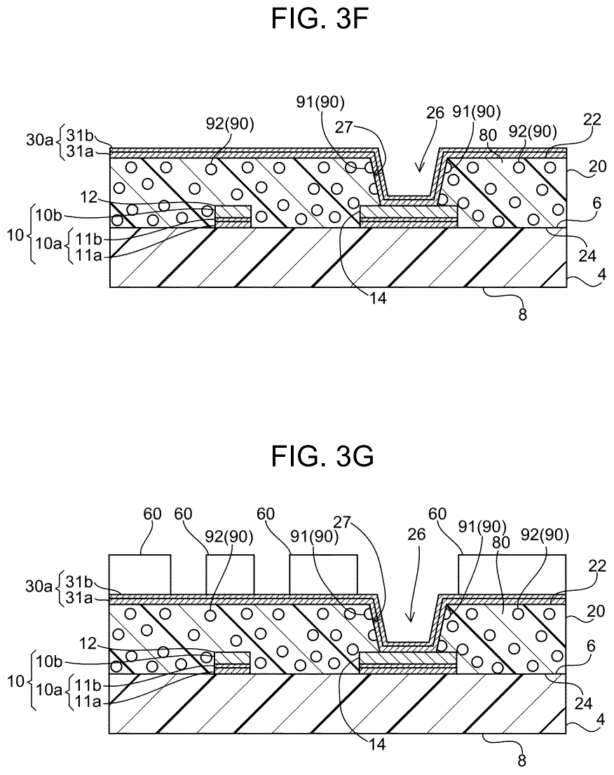

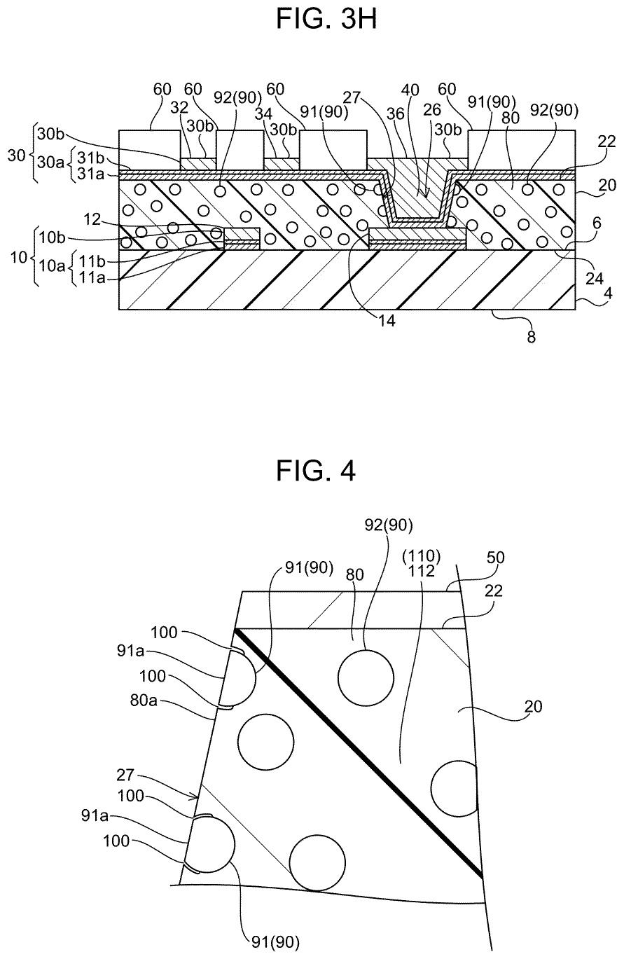

FIGS. 3A-3F illustrate a method for manufacturing the printed wiring board 2 of the embodiment. FIGS. 3A-3C and 3E-3F are cross-sectional views. FIG. 3D is an enlarged cross-sectional view. FIG. 3A illustrates the insulating layer 4 and the first conductor layer 10 formed on the third surface 6 of the insulating layer 4. The first conductor layer 10 is formed using a semi-additive method. The first layer (11a) and the second layer (11b) are formed by sputtering. The electrolytic plating layer (10b) is formed by electrolytic plating.

As illustrated in FIG. 3B, the first resin insulating layer 20 and a protective film 50 are formed on the insulating layer 4 and the first conductor layer 10. The second surface 24 of the first resin insulating layer 20 faces the third surface 6 of the insulating layer 4. The protective film 50 is formed on the first surface 22 of the first resin insulating layer 20. The first resin insulating layer 20 has the resin 80 and the inorganic particles 90 (the second inorganic particles 92). The inorganic particles 90 are embedded in the resin 80.

The protective film 50 completely covers the first surface 22 of the first resin insulating layer 20. The protective film 50 is, for example, a film formed of polyethylene terephthalate (PET). A layer of a release agent is formed between the protective film 50 and the first resin insulating layer 20.

As illustrated in FIG. 3C, laser (L) is irradiated from above the protective film 50. The laser (L) penetrates the protective film 50 and the first resin insulating layer 20. The via hole 26 for a via conductor reaching the pad 14 of the first conductor layer 10 is formed. The laser (L) is, for example, UV laser, or CO2 laser. The pad 14 is exposed from the via hole 26. When the via hole 26 is formed, the first surface 22 is covered by the protective film 50. Therefore, when the via hole 26 is formed, even when the resin scatters, adherence of the resin to the first surface 22 is suppressed.

FIG. 3D illustrates an inner wall surface (27b) of the via hole 26 after the laser irradiation. The inner wall surface (27b) is formed of the resin 80 and the inorganic particles 90 protruding from the resin 80. In order to control a shape of the inner wall surface, the inner wall surface (27b) after the laser irradiation is treated. It is preferable to selectively remove the inorganic particles 90 protruding from the resin 80. By the removal, the first inorganic particles 91 are formed from the inorganic particles 90. For example, the inorganic particles 90 protruding from the resin 80 may be selectively removed by treating the inner wall surface (27b) after the laser irradiation with a chemical. Or, the inorganic particles 90 protruding from the resin 80 may be selectively removed by treating the inner wall surface (27b) after the laser irradiation with plasma. The selectively removing of the inorganic particles 90 includes that an etching rate of the inorganic particles 90 is greater than an etching rate of the resin 80. For example, a difference in etching rate between the two is 10 or more times. Or, the difference in etching rate between the two is 50 or more times. Or, the difference in etching rate between the two is 100 or more times. By treating the inner wall surface (27b) after the laser irradiation, the first inorganic particles 91 having the first smooth surfaces (91a) (see FIG. 2) are obtained. Further, by controlling conditions for treating the inner wall surface (27b) after the laser irradiation, the shape of the inner wall surface (27b) can be controlled. Examples of the conditions are a temperature, a concentration, a time, a type of gas, and a pressure. The etching rate of the inorganic particles 90 and the etching rate of the resin are controlled.

By irradiating the first resin insulating layer 20 with the laser (L), some of the second inorganic particles 92 embedded in the resin 80 form the inner wall surface (27b) after the laser irradiation. The second inorganic particles 92 forming the inner wall surface (27b) after the laser irradiation are each formed of a protruding portion (P) protruding from the resin 80 and a portion (E) embedded in the resin 80. The inner wall surface (27b) after the laser irradiation is treated. For example, the inner wall surface (27b) is treated with plasma of a gas containing tetrafluoromethane. The protruding portions (P) are selectively removed and the inner wall surface 27 (see FIGS. 1 and 2) of the embodiment is formed. The first inorganic particles 91 are formed from the second inorganic particles 92. By selectively removing the protruding portions (P), the first inorganic particles 91 having the first smooth surfaces (91a) are formed. When the second inorganic particles 92 having spherical shapes are cut along a smooth surface, the shapes of the first inorganic particles 91 are obtained. The inner wall surface 27 is formed of the surface (80a) of the resin 80 and the first smooth surfaces (91a) of the first inorganic particles 91, and the surface (80a) and the first smooth surfaces (91a) are positioned on substantially the same plane. For example, when the seed layer (30a) is formed on the inner wall surface (27b) by sputtering, the protruding portions (P) inhibit growth of a sputtering film. For example, a continuous seed layer (30a) is not formed on the inner wall surface (27b). Or, the seed layer (30a) is increased in thickness. A fine conductor circuit cannot be formed. In the embodiment, the projecting portions (P) are removed. The seed layer (30a) formed by sputtering can be reduced in thickness. Even when the seed layer (30a) formed by sputtering is thin, a continuous seed layer (30a) can be obtained.

No unevenness is formed on the inner wall surface 27. The inner wall surface 27 is formed smooth. By controlling the conditions for treating the inner wall surface (27b) after the laser irradiation, a size of unevenness is controlled.

The inside of the via hole 26 is cleaned. By cleaning the inside of the via hole 26, resin residues generated when the via hole 26 is formed are removed. The cleaning of the inside of the via hole 26 is performed using plasma. That is, the cleaning is performed with a dry process. A gas of the dry process is a mixed gas of a halogen-based gas (such as a fluorine-based gas or a chlorine-based gas) and an O2 gas or is a halogen-based gas (such as a fluorine-based gas or a chlorine-based gas) or an O2 gas alone. The cleaning includes a desmear treatment. The first surface 22 of the first resin insulating layer 20 is covered by the protective film 50, and thus, is not affected by the plasma. No unevenness is formed on the first surface 22 of the first resin insulating layer 20. The first surface 22 is not roughened.

When treating the inner wall surface (27b) after the laser irradiation includes cleaning the inside of the via hole 26, cleaning the inside of the via hole 26 may be omitted.

As illustrated in FIG. 3E, after cleaning the inside of the via hole 26, the protective film 50 is removed from the first resin insulating layer 20. When treating the inner wall surface (27b) after the laser irradiation includes cleaning the inside of the via hole 26, the protective film 50 is removed from the first resin insulating layer 20 after treating the inner wall surface (27b) after the laser irradiation. When the inner wall surface (27b) after the laser irradiation is treated, the protective film 50 covers the first surface 22 of the first resin insulating layer 20. After the protective film 50 is removed, the first surface 22 of the first resin insulating layer 20 is not roughened. Therefore, the first surface 22 is formed smooth. The first surface 22 has, for example, an arithmetic mean roughness (Ra) of 0.02 μm or more and 0.06 μm or less.

As illustrated in FIG. 3F, the seed layer (30a) is formed on the first surface 22 of the first resin insulating layer 20. The seed layer (30a) is formed by sputtering. The formation of the seed layer (30a) is performed in a dry process. The first layer (31a) is formed on the first surface 22 by sputtering. At the same time, the first layer (31a) is formed on the inner wall surface 27 and the pad 14, which are exposed from the via hole 26, by sputtering. After that, the second layer (31b) is formed on the first layer (31a) by sputtering. The seed layer (30a) is also formed on the upper surface of the pad 14 exposed from the via hole 26 and on the inner wall surface 27 of the via hole 26. The first layer (31a) is formed of an alloy containing copper, silicon and aluminum. The second layer (31b) is formed of copper.

As illustrated in FIG. 3G, a plating resist 60 is formed on the seed layer (30a). The plating resist 60 has openings for forming the first signal wiring 32, the second signal wiring 34, and the land 36 (see FIG. 1).

As illustrated in FIG. 3H, the electrolytic plating layer (30b) is formed on the seed layer (30a) exposed from the plating resist. The electrolytic plating layer (30b) is formed of copper. The electrolytic plating layer (30b) fills the via hole 26. The first signal wiring 32, the second signal wiring 34, and the land 36 are formed by the seed layer (30a) and the electrolytic plating film (30b) on the first surface 22. The second conductor layer 30 is formed. The first via conductor 40 is formed by the seed layer (30a) and the electrolytic plating film (30b) in the via hole 26. The first via conductor 40 connects the pad 14 and the land 36. The first signal wiring 32 and the second signal wiring 34 form a pair wiring.

The plating resist is removed. The seed layer (30a) exposed from the electrolytic plating layer (30b) is removed by etching. The second conductor layer 30 and the first via conductor 40 are formed at the same time.

After that, on the second conductor layer 30 and the first surface 22, the second resin insulating layer 120, the third conductor layer 130 and the second via conductor 140 are formed. The second resin insulating layer 120, the third conductor layer 130, and the second via conductor 140 are formed using the same methods as the first resin insulating layer 20, the second conductor layer 30, and the first via conductor 40. The printed wiring board 2 of the embodiment (see FIG. 1) is obtained.

In the printed wiring board 2 of the embodiment (see FIGS. 1 and 2), in the first resin insulating layer 20, the inner wall surface 27 of the via hole 26 is formed of the surface (80a) of the resin 80 and the first smooth surfaces (91a) of the first inorganic particles 91. The surface (80a) and the first smooth surfaces (91a) form a substantially common surface. As a result, the inner wall surface 27 is formed smooth. Therefore, the seed layer (30a) having a uniform thickness is formed on the inner wall surface 27 of the via hole 26. The seed layer (30a) is formed thin (see FIG. 3F). When the seed layer (30a) is removed, an etching amount is small. Therefore, an etching amount of the electrolytic plating layer (30b) is small. The second conductor layer 30 having the first signal wiring 32 and the second signal wiring 34 has a width as designed. Further, since the inner wall surface 27 is formed smooth, the surface of the seed layer (30a) becomes smooth. As a result, a filling property of the electrolytic plating layer (30b) is improved. Formation of a stress concentration site (for example, an uneven part) in the electrolytic plating layer (30b) that forms an inner layer of the first via conductor 40 is suppressed. As a result, occurrence of a crack in the electrolytic plating layer (30b), which is an inner layer of the first via conductor 40, can be suppressed. Further, since the inner wall surface 27 is formed smooth, occurrence of a void between the inner wall surface 27 and the first via conductor 40 is suppressed. Also in the second resin insulating layer 120, similar to the first resin insulating layer 20, the inner wall surface 127 of the via hole 126 is formed smooth by the surface (180a) of the resin 180 and the first smooth surfaces (191a) of the first inorganic particles 191. Therefore, the third second conductor layer 130 having the first signal wiring 132 and the second signal wiring 134 has a width as designed. Further, occurrence of a crack in the electrolytic plating layer (130b), which is an inner layer of the second via conductor 140, can be suppressed. Further, occurrence of a void between the inner wall surface 127 and the second via conductor 140 is suppressed. Therefore, reliability of the printed wiring board 2 is improved. That is, a high quality printed wiring board 2 is provided.

In the printed wiring board 2 of the embodiment, the first surface 22 of the first resin insulating layer 20 is formed only of the resin 80. The inorganic particles 90 are not exposed on the first surface 22. Similarly, the fifth surface 122 of the second resin insulating layer 120 is formed only of the resin 180. The inorganic particles 190 are not exposed on the fifth surface 122. No unevenness is formed on the first surface 22 and the fifth surface 122. An increase in standard deviation of a relative permittivity in a portion near the first surface 22 of the first resin insulating layer 20 is suppressed. An increase in standard deviation of a relative permittivity in a portion near the fifth surface 122 of the second resin insulating layer 120 is suppressed. The relative permittivity of the first surface 22 and the relative permittivity of the fifth surface 122 do not vary significantly depending on a location. Even when the first signal wiring 32 and the second signal wiring 34 are in contact with the first surface 22, a difference in propagation speed of an electric signal between the first signal wiring 32 and the second signal wiring 34 can be reduced. Similarly, even when the first signal wiring 132 and the second signal wiring 134 are in contact with the fifth surface 122, a difference in propagation speed of an electric signal between the first signal wiring 132 and the second signal wiring 134 can be reduced. Therefore, in the printed wiring board 2 of the embodiment, noise is suppressed. Even when a logic IC is mounted on the printed wiring board 2 of the embodiment, data transmitted via the first signal wiring (32, 132) and data transmitted via the second signal wiring (34, 134) arrive at the logic IC substantially without delay. Malfunction of a logic IC can be suppressed. For example, even when a length of the first signal wiring (32, 132) and a length of the second signal wiring (34, 134) are 5 mm or more, a difference in propagation speed between the two can be reduced. Even when the length of the first signal wiring (32, 132) and the length of the second signal wiring (34, 134) are 10 mm or more and 20 mm or less, malfunction of the logic IC can be suppressed. A high quality printed wiring board 2 is provided.

### First Alternative Example

In a first alternative example of the embodiment, the first layers (11a, 31a, 131a) of the seed layers (10a, 30a 130a) are formed of copper and a second element. The second element is selected from silicon, aluminum, titanium, nickel, chromium, carbon, oxygen, tin, calcium, magnesium, iron, molybdenum, and silver. The first layers (11a, 31a, 131a) are formed of an alloy containing copper. The second layers (11b, 31b, 131b) are formed of copper. An amount of copper (atomic weight %) forming the second layers (11b, 31b, 131b) is 99.9% or more, and preferably 99.95% or more.

It is also possible that the first layers (11a, 31a, 131a) of the seed layers (10a, 30a, 130a) are formed of any one of silicon, aluminum, titanium, nickel, chromium, carbon, oxygen, tin, calcium, magnesium, iron, molybdenum, and silver.

### Second Alternative Example

In a second alternative example of the embodiment, the conditions for treating the inner wall surfaces (27b, 127b) after the laser irradiation are controlled. Therefore, as illustrated in FIG. 4, the surface (80a) of the resin 80 and the first smooth surfaces (91a) of the first inorganic particles 91, which form the inner wall surface 27, form substantially the same plane. FIG. 4 is an enlarged cross-sectional view illustrating the inner wall surface 27 after the treatment. The inner wall surface 127 after the treatment has a cross section similar to that of the inner wall surface 27 after the treatment, and thus, illustration thereof is omitted. Distances between the first smooth surfaces (91a) and the surface (80a) of the resin 80 are 5 μm or less. Therefore, even when there are gaps 100 between the first inorganic particles 91 and the resin 80 formed around the first inorganic particles 91, the seed layer (30a) can be formed in the gaps 100. In this case, the seed layer (30a) is formed on the inner wall surface 27 and in the gaps 100. When distances between the first smooth surfaces (91a) and bottoms of the gaps 100 are 5 μm or less, the seed layer (30a) formed by sputtering is unlikely to peel off from the inner wall surface 27. The distances between the first smooth surfaces (91a) and the bottoms of the gaps 100 are preferably 3 μm or less. Variation in the thickness of the seed layer (30a) on the inner wall surface 27 can be reduced. For the same reason, the seed layer (130a) formed by sputtering is unlikely to peel off from the inner wall surface 127. Further, variation in the thickness of the seed layer (130a) on the inner wall surface 127 can be reduced.

In the printed wiring board 2, the first resin insulating layer 20 contains the resin 80 and the inorganic particles 90. However, the first resin insulating layer 20 may also contain a fiber reinforcing material. The second resin insulating layer 120 contains the resin 180 and the inorganic particles 190. However, the second resin insulating layer 120 may also contain a fiber reinforcing material. As the fiber reinforcing material, for example, a glass cloth, a glass nonwoven fabric, or an aramid nonwoven fabric may be used. The fiber reinforcement material may be contained in both the first resin insulating layer 20 and the second resin insulating layer 120 or may be contained in only one of the two.

In the printed wiring board 2, two resin insulating layers are laminated. However, it is also possible that three or more resin insulating layers are laminated.

A printed wiring board according to an embodiment of the present invention is not limited to those having the structures exemplified in the drawings and those having the structures, shapes, and materials exemplified in the present specification. As described above, a printed wiring board according to an embodiment of the present invention may have any laminated structure. For example, the printed wiring board of the embodiment may be a coreless substrate that does not include a core substrate. The printed wiring board of the embodiment can include any number of conductor layers and any number of insulating layers.

A method for manufacturing a printed wiring board according to an embodiment of the present invention is not limited to the method described with reference to the drawings. For example, the conductor layers may be formed using a full additive method. Further, each of the insulating layers may be formed using a resin in any form without being limited to a film-like resin. In a method for manufacturing a printed wiring board according to an embodiment of the present invention, it is also possible that any process other than the processes described above is added, or some of the processes described above are omitted.

Japanese Patent Application Laid-Open Publication No. 2005-268517 describes a multilayer wiring substrate in which multiple resin insulating layers and multiple wiring conductor layers are alternately laminated. Wiring conductor layers positioned above and below an insulating layer are electrically connected via a penetrating conductor formed in the insulating layer. The penetrating conductors are stacked such that the penetrating conductor formed in an uppermost insulating layer is continuously connected to the penetrating conductor on a lower-layer side in an up-down direction. An upper end of the penetrating conductor formed in the uppermost insulating layer protrudes from the insulating layer.

In Japanese Patent Application Laid-Open Publication No. 2005-268517, the penetrating conductors are embedded in through holes provided in the insulating layers. When an inner wall surface (inner peripheral surface) of a through hole is uneven, a site is formed on an outer wall surface (outer peripheral surface) of the penetrating conductor where a stress corresponding to the unevenness is likely to concentrate. It is thought that when a stress concentrates on the penetrating conductor, a crack occurs in the penetrating conductor.

A printed wiring board according to an embodiment of the present invention includes a laminate that is formed by alternately laminating multiple resin insulating layers and multiple conductor layers, the resin insulating layers containing a resin and inorganic particles and having via holes, and via conductors that are respectively formed in the via holes of the resin insulating layers and connect the conductor layers adjacent to each other in a lamination direction. An inner wall surface of each of the via holes of the resin insulating layers is formed of the resin and the inorganic particles, the inorganic particles include first inorganic particles having first smooth surfaces forming the inner wall surface, and second inorganic particles embedded in the resin insulating layers, and the via conductors overlap in the lamination direction and are each formed of a seed layer and an electrolytic plating layer on the seed layer.

In a printed wiring board according to an embodiment of the present invention, the resin insulating layers contain inorganic particles and a resin. The resin insulating layers have via holes. The inner wall surface of each of the via holes is in contact with the seed layer of the via conductors. The inner wall surface of each of the via holes is formed of the resin and the inorganic particles. By making the inner wall surface of each of the via holes smooth, a surface of the seed layer formed on the inner wall surface becomes smooth, and a filling property of the electrolytic plating layer is improved. As a result, formation of a stress concentration site in the electrolytic plating layer that forms an inner layer of the via conductors is suppressed. Occurrence of a crack in the inner layer of the via conductors can be suppressed.

Obviously, numerous modifications and variations of the present invention are possible in light of the above teachings. It is therefore to be understood that within the scope of the appended claims, the invention may be practiced otherwise than as specifically described herein.

1. A printed wiring board, comprising:
a laminate comprising a plurality of resin insulating layers and a plurality of conductor layers; and
a plurality of via conductors formed in via holes of the resin insulating layers and each comprising a seed layer and an electrolytic plating layer formed on the seed layer such that the via conductors connect the conductor layers adjacent to each other and that the via conductors include a first via conductor and a second via conductor formed on the first via conductor in a lamination direction of the laminate,
wherein the resin insulating layers include resin and inorganic particles such that the inorganic particles include first inorganic particles having smooth surfaces and second inorganic particles embedded in the resin insulating layers and that an inner wall surface of each of the via holes in the resin insulating layers includes the resin and the smooth surfaces of the first inorganic particles.

2. The printed wiring board according to claim 1, wherein the laminate is formed such that the smooth surfaces of the first inorganic particles are cut surfaces of the inorganic particles.

3. The printed wiring board according to claim 1, wherein the laminate is formed such that a surface of the resin and the smooth surfaces on the inner wall surface are flush with each other.

4. The printed wiring board according to claim 1, wherein the plurality of via conductors is formed such that the seed layer in each of the via conductors is a sputtering film.

5. The printed wiring board according to claim 4, wherein the plurality of via conductors is formed such that the sputtering film in each of the via conductors includes a first layer in contact with the inner wall surface of each of the via holes and a second layer formed on the first layer.

6. The printed wiring board according to claim 1, wherein the laminate is formed such that each of the conductor layers includes a seed layer formed on a surface of a respective one of the resin insulating layers, and an electrolytic plating layer formed on the seed layer on the surface of the respective one of the resin insulating layers and that the surface of the respective one of the resin insulating layers is formed only of the resin.

7. The printed wiring board according to claim 4, wherein the plurality of via conductors is formed such that the sputtering film in each of the via conductors includes a first layer comprising a copper alloy in contact with the inner wall surface of each of the via holes and a second layer comprising copper formed on the first layer.

8. The printed wiring board according to claim 2, wherein the laminate is formed such that a surface of the resin and the smooth surfaces on the inner wall surface are flush with each other.

9. The printed wiring board according to claim 2, wherein the plurality of via conductors is formed such that the seed layer in each of the via conductors is a sputtering film.

10. The printed wiring board according to claim 9, wherein the plurality of via conductors is formed such that the sputtering film in each of the via conductors includes a first layer in contact with the inner wall surface of each of the via holes and a second layer formed on the first layer.

11. The printed wiring board according to claim 2, wherein the laminate is formed such that each of the conductor layers includes a seed layer formed on a surface of a respective one of the resin insulating layers, and an electrolytic plating layer formed on the seed layer on the surface of the respective one of the resin insulating layers and that the surface of the respective one of the resin insulating layers is formed only of the resin.

12. The printed wiring board according to claim 9, wherein the plurality of via conductors is formed such that the sputtering film in each of the via conductors includes a first layer comprising a copper alloy in contact with the inner wall surface of each of the via holes and a second layer comprising copper formed on the first layer.

13. The printed wiring board according to claim 3, wherein the plurality of via conductors is formed such that the seed layer in each of the via conductors is a sputtering film.

14. The printed wiring board according to claim 13, wherein the plurality of via conductors is formed such that the sputtering film in each of the via conductors includes a first layer in contact with the inner wall surface of each of the via holes and a second layer formed on the first layer.

15. The printed wiring board according to claim 3, wherein the laminate is formed such that each of the conductor layers includes a seed layer formed on a surface of a respective one of the resin insulating layers, and an electrolytic plating layer formed on the seed layer on the surface of the respective one of the resin insulating layers and that the surface of the respective one of the resin insulating layers is formed only of the resin.

16. The printed wiring board according to claim 13, wherein the plurality of via conductors is formed such that the sputtering film in each of the via conductors includes a first layer comprising a copper alloy in contact with the inner wall surface of each of the via holes and a second layer comprising copper formed on the first layer.

17. The printed wiring board according to claim 4, wherein the laminate is formed such that each of the conductor layers includes a seed layer formed on a surface of a respective one of the resin insulating layers, and an electrolytic plating layer formed on the seed layer on the surface of the respective one of the resin insulating layers and that the surface of the respective one of the resin insulating layers is formed only of the resin.

18. The printed wiring board according to claim 1, wherein the laminate is formed such that the smooth surfaces of the first inorganic particles have an arithmetic mean roughness Ra of 1.0 μm or less.

19. The printed wiring board according to claim 1, wherein the laminate is formed such that each of the conductor layers includes a seed layer formed on a surface of a respective one of the resin insulating layers, and an electrolytic plating layer formed on the seed layer on the surface of the respective one of the resin insulating layers and that the surface of the respective one of the resin insulating layers is formed only of the resin and has an arithmetic mean roughness Ra in a range of 0.02 μm to 0.06 μm.

20. The printed wiring board according to claim 1, wherein the laminate is formed such that the smooth surfaces of the first inorganic particles have an arithmetic mean roughness Ra of 1.0 μm or less, that each of the conductor layers includes a seed layer formed on a surface of a respective one of the resin insulating layers, and an electrolytic plating layer formed on the seed layer on the surface of the respective one of the resin insulating layers and that the surface of the respective one of the resin insulating layers is formed only of the resin and has an arithmetic mean roughness Ra in a range of 0.02 μm to 0.06 μm.
